(19) United States
(12) Patent Application Publication
(10) Pub. No.: US 2010/0180946 A1
(43) Pub. Date: Jul. 22, 2010

(54) INCREASING THE ANGULAR RANGE OF LIGHT COLLECTION IN SOLAR COLLECTORS/CONCENTRATORS

(75) Inventors: Russell Wayne Gruhlke, Milpitas, CA (US); Kasra Khazeni, San Jose, CA (US)

Correspondence Address: KNOBBE, MARTENS, OLSON & BEAR, LLP, 2040 MAIN STREET, FOURTEENTH FLOOR, IRVINE, CA, 92614, US

(73) Assignee: QUALCOMM MEMS Technologies, Inc., San Diego, CA (US)

(21) Appl. No.: 12/561,873

(22) Filed: Sep. 17, 2009

Related U.S. Application Data
(60) Provisional application No. 61/098,179, filed on Sep. 18, 2008.

(51) Int. Cl. H01L 31/00; G02B 27/42; G02B 5/32; B29D 11/00

(52) U.S. Cl. 136/259; 359/558; 359/15; 264/2.7

(57) ABSTRACT

In various embodiments described herein, a device comprises an angle turning layer disposed over a light guiding layer that is optically coupled to a photocell. A plurality of surface features is formed on one of the surfaces of the light guiding layer. The surface features can comprise facets that are angled with respect to each other. The angle turning layer can comprise diffractive features that are volume features or surface-relief features. Light incident on the angle turning layer at a first angle is turned towards the light guiding layer at a second angle and subsequently redirected at a third angle by the surface features of the light guiding layer and guided through the light guide by multiple total internal reflections. The guided light is directed towards a photocell.

### CROSS-REFERENCE TO RELATED APPLICATIONS

This application claims priority benefit under 35 U.S.C. §119(e) of U.S. Provisional Application Ser. No. 61/098,179 filed on Sep. 18, 2008, titled “INCREASING THE ANGULAR RANGE OF LIGHT COLLECTION IN SOLAR COLLECTORS/CONCENTRATORS” (Atty. Docket No. QMRC.010PR), which is hereby expressly incorporated herein by reference in its entirety.

### BACKGROUND OF THE INVENTION

1. Field of the Invention

The present invention relates to the field of light collectors and concentrators and more particularly to using micro-structured thin films to collect and concentrate solar radiation.

2. Description of the Related Art

Solar energy is a renewable source of energy that can be converted into other forms of energy such as heat and electricity. Major drawbacks in using solar energy as a reliable source of renewable energy are low efficiency in converting light energy to heat or electricity and the variation in the solar energy depending on the time of the day and the month of the year.

A photovoltaic (PV) cell can be used to convert solar energy to electrical energy. Systems using PV cells can have conversion efficiencies between 10-20%. PV cells can be made very thin and are not big and bulky as other devices that use solar energy. PV cells can range in width and length from a few millimeters to 10's of centimeters. The individual electrical output from one PV cell may range from a few milliWatts to a few Watts. Several PV cells may be connected electrically and packaged to produce a sufficient amount of electricity.

Solar concentrators can be used to collect and focus solar energy to achieve higher conversion efficiency in PV cells. For example, parabolic mirrors can be used to collect and focus light on a device that converts light energy in to heat and electricity. Other types of lenses and mirrors can also be used to significantly increase the conversion efficiency but they do not overcome the variation in amount of solar energy received depending on time of the day, month of the year or weather conditions. Further the systems employing lenses/mirrors tend to be bulky and heavy because the lenses and mirrors that are required to efficiently collect and focus sunlight have to be large.

PV cells can be used in wide range of applications such as providing power to satellites and space shuttles, providing electricity to residential and commercial properties, charging automobile batteries and other navigation instruments. Accordingly, for many applications it is also desirable that these light collectors and/or concentrators are compact in size.

### SUMMARY

Various embodiments described herein comprise light guides for collecting/concentrating ambient light and directing the collected light to a photocell. The light guide may include one or more holographic layers disposed forward to the light guide. The holographic layers may comprise volume holograms or surface relief features. The holographic layers may turn light incident at a first angle and redirect incident light at a second angle towards a plurality of prismatic features. The prismatic features may be disposed rearward to the light guide. Light incident on the prismatic features may be further redirected so as to propagate the light through the light guide by multiple total internal reflections. The prismatic features may comprise facets that reflect light. In some embodiments, the facets may be angled with respect to each other. The photocell is optically coupled to the light guide. In some embodiments the photocell may be disposed adjacent to the light guide. In some other embodiments, the photocell may be disposed at one corner of the light guide. In various embodiments, the photocell may be disposed below the light guide. In some embodiments, the light guide may be disposed on a substrate. The substrate may comprise glass, plastic, electrochromic glass, smart glass, etc.

Various embodiments described herein comprise a light collecting device. The light collecting device comprises a means for guiding light, the light guiding means having top and bottom surfaces. In various embodiments, the light guiding means is configured to guide light therein by multiple total internal reflections at said top and bottom surfaces. In various embodiments, the light collecting device comprises a plurality of means for diffracting light, the light diffracting means disposed to receive light at a first angle with respect to the normal to the top surface of said light guiding means. The light collecting device may additionally comprise a plurality of means for turning light, said light turning means disposed rearward of the plurality of diffracting means. In various embodiments, the plurality of diffracting means is configured to redirect the light at a second angle towards the plurality of light turning means. In various embodiments, the plurality of light turning means are configured to turn the light redirected by the diffracting means such that the light is guided in the light guiding means by total internal reflection from said top and bottom surfaces of the light guiding means. In some embodiments, the light guiding means comprises a light guide, or the plurality of diffracting means comprises a plurality of diffractive features, or the plurality of light turning means comprises a plurality of prismatic features.

In various embodiments, a method of manufacturing a light collecting device is disclosed. The method comprises providing a light guide having top and bottom surfaces. In various embodiments, the light guide is configured to guide light therein by multiple total internal reflections at said top and bottom surfaces. The method comprises providing a plurality of diffractive features with respect to the light guide. In various embodiments, the plurality of diffractive features is configured to receive light at a first angle with respect to the normal to the top surface of the light guide. The method further comprises providing a plurality of prismatic features with respect to the light guide. In various embodiments, the plurality of prismatic features are disposed rearward of the plurality of diffractive features. In various embodiments, the plurality of prismatic features can be disposed rearward of the light guide. In various embodiments, the plurality of prismatic features can be provided by molding, embossing or etching. In various embodiments, the plurality of diffractive features can be disposed forward of the light guide. In some embodiments, the plurality of diffractive features can be provided in a layer that is disposed forward of the light guide.

### BRIEF DESCRIPTION OF THE DRAWINGS

Example embodiments disclosed herein are illustrated in the accompanying schematic drawings, which are for illustrative purposes only.

FIG. 1A illustrates the side view of a prismatic light guide comprising a plurality of prismatic features configured to collect and guide light incident at near normal incidence with respect to the light guide to a photo cell.

FIG. 1B illustrates an enlarged side view of the plurality of prismatic features.

FIG. 1C shows the perspective view of the embodiment described in FIG. 1A.

FIG. 1D illustrates a side view of a light guide comprising a plurality of prismatic features that will not guide light incident at certain angles.

FIG. 2A illustrates a side view of an embodiment comprising a prismatic light guide and a holographic layer further comprising multiple holograms configured to collect and guide light to a photovoltaic cell disposed along one edge of the light guide.

FIG. 2B illustrates a side view of an embodiment comprising a prismatic light guide and a holographic layer further comprising multiple holograms configured to collect and guide light to two photovoltaic cells disposed along two edges of the light guide.

FIG. 3 illustrates a side view of an embodiment comprising a prismatic light guide and multiple holographic layers.

FIG. 4A illustrates a side view of an embodiment comprising multiple prismatic light guide layers stacked with offset prismatic features and multiple holographic layers.

FIG. 4B illustrates a side view of an embodiment comprising single prismatic light guide layer with prismatic features having different shapes and multiple holographic layers.

FIG. 5A illustrates an embodiment comprising thereof a light guide with prismatic features that are arranged concentrically with a photo cell placed at the center and a holographic layer.

FIG. 5B illustrates an embodiment comprising a light guide with curvilinear prismatic features, a holographic layer and a photo cell placed at one corner.

FIG. 6 illustrates an array of microstructure patterns disposed rearward of a holographic film.

FIG. 7 illustrates an embodiment wherein a light guide comprising a holographic layer is beveled to direct light to a photocell below the light guide.

FIG. 8 shows a light collecting plate, sheet or film optically coupled to photo cells placed on the roof and on the windows of a residential dwelling.

FIG. 9 shows an embodiment wherein a light collecting plate, sheet or film optically coupled to photo cells is placed on the roof of an automobile.

FIG. 10 illustrates a light collecting plate, sheet or film optically coupled to photo cells that is attached to the body of a laptop.

FIG. 11 shows an example of attaching light collecting plate, sheet or film optically coupled to photo cells that is attached to an article of clothing.

FIG. 12 shows an example of placing light collecting plate, sheet or film optically coupled to photo cells on shoes.

FIG. 13 shows an embodiment wherein a light collecting plate, sheet or film optically coupled to photo cells is attached to the wings and windows of an airplane.

FIG. 14 shows an embodiment wherein a light collecting plate, sheet or film optically coupled to photo cells is attached to a sail boat.

FIG. 15 shows an embodiment wherein a light collecting sheet, plate or film optically coupled to photo cells is attached to a bicycle.

FIG. 16 illustrates an embodiment wherein a light collecting plate, sheet or film optically coupled to photo cells is attached to a satellite.

FIG. 17 shows an embodiment wherein a light collect sheet that is substantially flexible to be rolled is optically coupled to photo cells.

### DETAILED DESCRIPTION OF THE PREFERRED EMBODIMENTS

The following detailed description is directed to certain specific embodiments of the invention. However, the invention can be embodied in a multitude of different ways. As will be apparent from the following description, the embodiments may be implemented in any device that is configured to collect, trap and concentrate radiation from a source. More particularly, it is contemplated that the embodiments described herein may be implemented in or associated with a variety of applications such as providing power to residential and commercial structures and properties, providing power to electronic devices such as laptops, PDAs, wrist watches, calculators, cell phones, camcorders, still and video cameras, mp3 players etc. In addition the embodiments described herein can be used in wearable power generating clothing, shoes and accessories. Some of the embodiments described herein can be used to charge automobile batteries or navigational instruments and to pump water. The embodiments described herein can also find use in aerospace and satellite applications. Other uses are also possible.

In various embodiments described herein, a solar collector and/or concentrator is coupled to a photo cell. The solar collector and/or concentrator comprises a light guide, for example, a plate, sheet or film with prismatic turning features formed thereon. Ambient light that is incident on the light guide is turned within the light guide by the prismatic features and guided through the light guide by total internal reflection. A photo cell is disposed along one or more edges of the light guide and light that is propagated along the light guide is coupled into the photo cell. Using the light guide to collect, concentrate and direct ambient light to photo cells may realize opto-electric devices that convert light energy into heat and electricity with increased efficiency and lower cost. The light guide may be formed as a plate, sheet or film. The light guide may be fabricated from a rigid or a semi-rigid material. In some embodiments, the light guide may be formed of a flexible material. In various embodiments, the light guide may comprise a thin film. The light guide may comprise prismatic features such as formed by grooves arranged in a linear fashion. In some embodiments, the prismatic features may have non-linear extent. For example, in some embodiments the prismatic features may be arranged along curves. One embodiment may comprise a thin film light guide with conical reflective features dispersed through the light guiding medium.

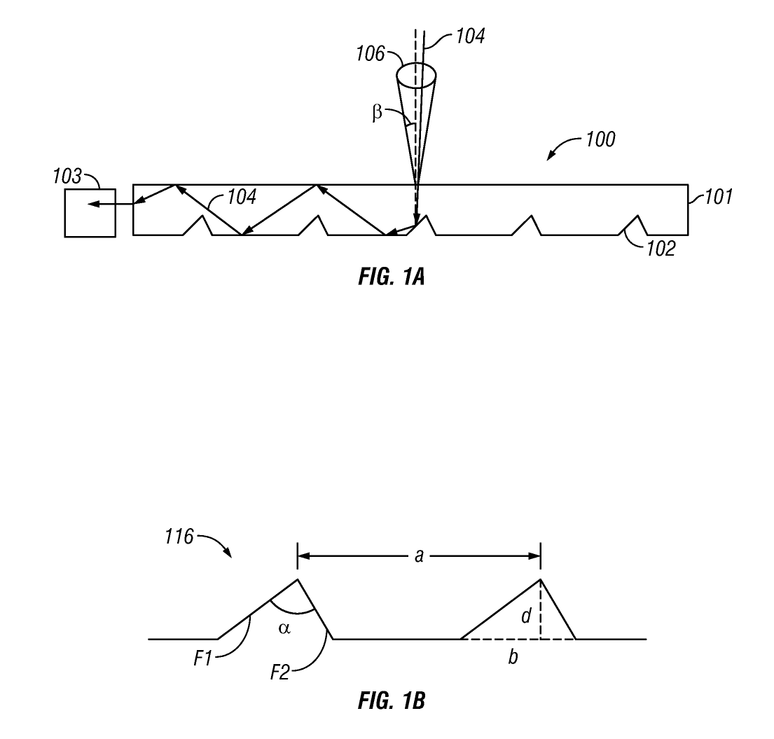

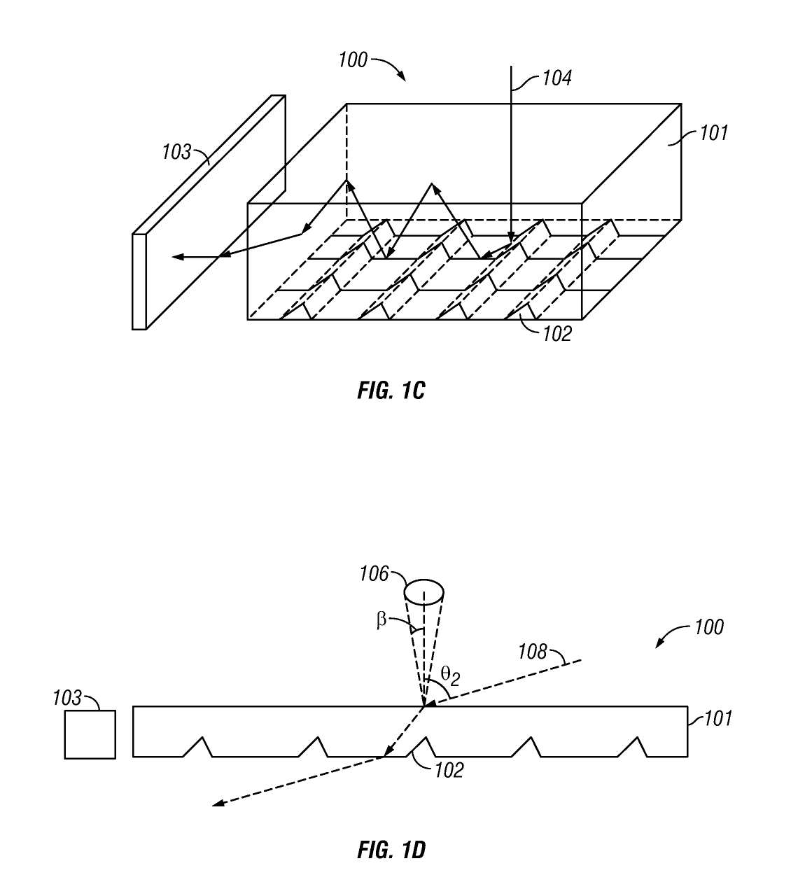

One embodiment of a prismatic light guide used to couple ambient light into a photo cell is shown in FIG. 1A. The photo cell may be a photovoltaic cell or a photo detector. FIG. 1A illustrates the side view of an embodiment 100 comprising a light guide 101 disposed with respect to a photo cell 103. In some embodiments, the light guide 101 may further comprise a substrate (not shown). A plurality of prismatic features 102 may be disposed in the light guide 101. The light guide 101 may comprise a top and bottom surface including a plurality of edges therebetween. In the embodiment illustrated in FIG. 1A the prismatic features are disposed on the bottom surface. Light incident on the light guide 101 may be redirected into the light guide 101 by the plurality of prismatic features 102 and guided within the light guide 101 by multiple total internal reflections at the top and bottom surface. The light guide 101 may comprise optically transmissive material that is transparent to radiation at one or more wavelengths that the photo cell is sensitive to. For example in one embodiment, the light guide 101 may be optically transmissive to wavelengths in the visible and near infra-red region. In other embodiments, the light guide 101 may be transparent to wavelengths in the ultra-violet or infra-red regions. The light guide 101 may be formed from rigid or semi-rigid material such as glass, acrylic, polycarbonate, polyester or cyclo-olefin polymer so as to provide structural stability to the embodiment. Alternatively the light guide 101 may be formed of flexible material such as a flexible polymer. Materials other than those specifically recited herein may also be used.

The top surface of the light guide 101 may be configured to receive ambient light. The light guide 101 can be bounded by an edge all around. Typically, the length and width of the light guide 101 may be substantially greater than the thickness of the light guide 101. The thickness of the light guide 101 may vary from 0.1 to 10 mm. The area of the light guide 101 may vary from 0.01 to 10000 cm². Dimensions outside these ranges, however are possible. In some embodiments, the refractive index of the material comprising the light guide 101 may be significantly higher than the surrounding so as to guide a large portion of the ambient light within the light guide 101 by total internal reflection (TIR).

The light guided in the light guide 101 may suffer losses due to absorption in the light guide and scattering from other facets. To reduce this loss in the guided light, in some embodiments the length of the light guide 101 can be limited to tens of inches so as to reduce the number of reflections. However, limiting the length of the light guide 101 may reduce the area over which light is collected. Thus in some embodiments, the length of the light guide 101 may be increased to greater than tens of inches. In some embodiments, optical coatings may be deposited on the surface of the light guide 101 to reduce scattering losses.

In one embodiment, as shown in FIG. 1A, the light guide 101 comprises prismatic features 102 disposed on the bottom surface of the light guide 101. The prismatic features may comprise elongated grooves formed on the bottom surface of the light guide 101. The grooves may be filled with an optically transmissive material. The prismatic features 102 may be formed on the bottom surface of the light guide 101 by molding, embossing, etching or other alternate techniques. Alternatively, the prismatic features 102 may be disposed on a film which may be laminated on the bottom surface of the light guide 101. In some embodiments comprising a prismatic film, light may be guided within the prismatic film alone. The prismatic features 102 may comprise a variety of shapes. For example, the prismatic features 102 may be linear v-grooves. Alternately, the prismatic features 102 may comprise curvilinear grooves or non-linear shapes. Other configurations are also possible.

FIG. 1B shows an enlarged view of prismatic features 102 in the form of a linear v-groove 116. The v-groove 116 comprises two planar facets F1 and F2 arranged with an angular separation a with respect to each other as shown in FIG. 1B. The angular separation a between the facets may vary from 15 degrees to 120 degrees. In some embodiments, the facets F1 and F2 may be of equal lengths. In some other embodiments, the length of one of the facets may be greater than the other. The distance between two consecutive v-grooves ‘a’ may vary between 5 μm to 500 μm. The width of the v-groove indicated by ‘b’ may vary between 0.001 mm to 0.100 mm while the depth of the v-groove indicated by ‘d’ may vary between 0.001 to 0.5 mm. Dimensions outside these ranges may also be used.

FIG. 1C shows the perspective view of the embodiment described in FIG. 1A. The embodiment described in FIG. 1C comprises rows of linear v-grooves arranged along the bottom surface of the light guide 101.

Referring to FIGS. 1A and 1C, a photo cell 103 is disposed laterally with respect to the light guide 101. The photo cell is configured to receive light guided through the light guide 101 by the prismatic features 102. The photo cell 103 may comprise a single or a multiple layer p-n junction and may be formed of silicon, amorphous silicon or other semiconductor materials such as Cadmium telluride. In some embodiments, photo cell 103 based on photo-electrochemical cells, polymer or nanotechnology may be used. Photo cell 103 may also comprise thin multispectrum layers. The multispectrum layers may further comprise nanocrystals dispersed in polymers. Several multispectrum layers may be stacked to increase efficiency of the photo cell 103. FIGS. 1A and 1C show an embodiment wherein the photo cell 103 is disposed along one edge of the light guide 101 (for example, to the left of the light guide 101). However, another photo cell may be disposed at the other edge of the light guide 101 as well (for example, to the right of the light guide 101). Other types of photocell and other configurations of positioning the photo cell(s) with respect to the light guide 101 are also possible.

The amount of light that can be collected and guided through a prismatic light guide may generally depend on the geometry, type and density of the prismatic features. In some embodiments, the amount of light collected may also depend upon the refractive index of the light guiding material, which determines the numerical aperture of the light guide. In some embodiments, the geometry of the prismatic features is such that only those rays of light whose angle of incidence lie within a certain angular cone (referred to herein as angular cone of acceptance) will be turned by the prismatic features into guided modes of the light guide while those rays of light whose angle of incidence lies outside that angular cone will be either transmitted or reflected out of the light guide. For example, in FIG. 1A, the geometry of the prismatic features 102 is such that that those rays of light whose angle of incidence lie within an angular cone 106 with semi-angle β (e.g. ray 104 that is substantially along the normal to the surface of the light guide 101) are redirected by the prismatic features 102 and guided within the light guide 101 by multiple reflections from the top and bottom surface of the light guide 101.

Those rays of light whose angle of incidence lie outside the cone 106 may be transmitted through the light guide 101. For example, in FIG. 1D, ray of light 108 is incident on the top surface of the light guide 101 at angle θ₂ such that ray of light 108 lies outside the cone 106. Ray of light 108 may be refracted into the light guide 101 such that it strikes a portion of the bottom surface of the light guide 101 that is devoid of prismatic features 102 and is subsequently transmitted through the light guide 101. In some embodiments, the angular cone of acceptance may be small. In some embodiments, the semi-angle β may be approximately 10 degrees.

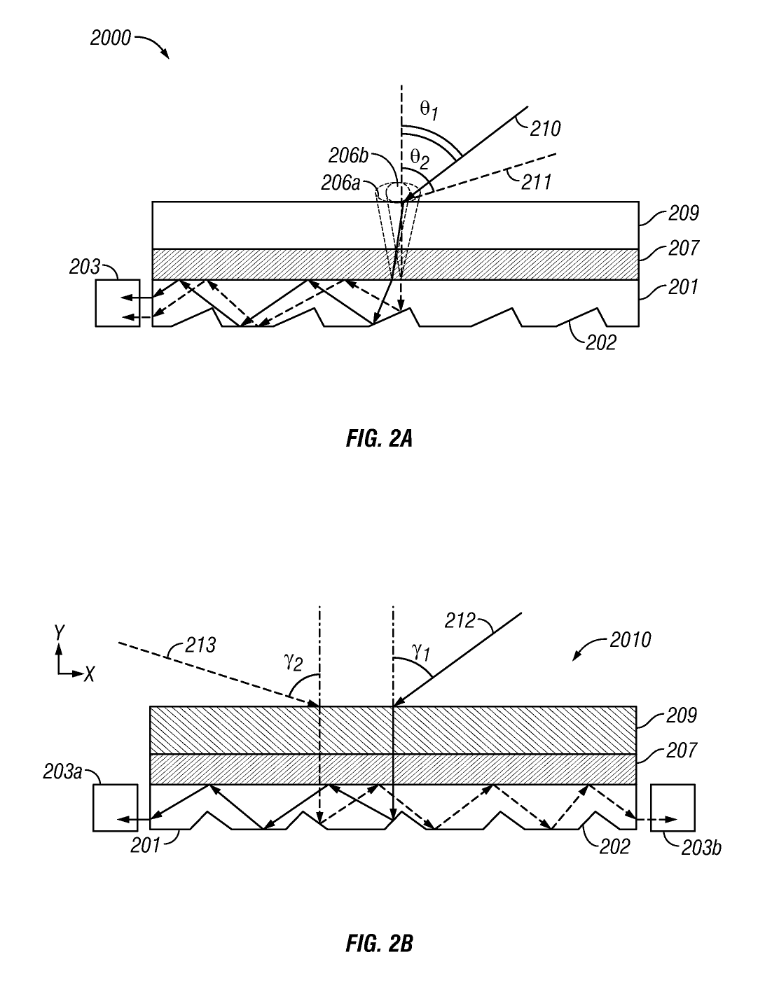

To increase the angular range of rays incident on the light guide that are guided within the light guide, it may be advantageous to dispose an angle turning layer forward of the prismatic light guide that can turn the rays of light whose angle of incidence lie outside the angular cone of acceptance such that they are incident on the prismatic light guide at an angle of incidence that lies within the angular cone of acceptance. This concept is discussed further with reference to FIG. 2A below.

FIG. 2A illustrates an embodiment 2000 comprising a prismatic light guide 201. Prismatic features 202 are disposed rearward of the prismatic light guide 201. The embodiment further comprises an angle turning layer 209 disposed forward of light guide 201. In some embodiments, the angle turning layer 209 may comprise a holographic layer. In some embodiments, the angle turning layer 209 may comprise volume features (e.g. volume holograms). In some embodiments, the angle turning layer 209 may comprise surface relief features (e.g. surface relief diffractive features that form surface holograms or surface diffractive optical elements, etc). In some embodiments, the angle turning layer may comprise volume features and surface relief diffractive features. In some embodiments, the prismatic light guide 201 and the angle turning layer 209 may be laminated together. The angle turning layer 209 may be joined to the prismatic light guide 201 with an adhesive layer 207. In some embodiments, the adhesive layer 207 may comprise pressure sensitive adhesive (PSA). In some embodiments, the refractive index of the adhesive layer 207 may be lower than the refractive index of the material comprising the prismatic light guide 201. For example, in one embodiment, the refractive index of the adhesive layer 207 can be approximately 1.47 while the prismatic light guide 201 may comprise a high refractive index material such as polycarbonate having refractive index approximately 1.59.

In the embodiment comprising a PSA layer having lower refractive index than the light guiding material light interacts with the light turning layer and is subsequently guided in the waveguide by multiple total internal reflections at the interface of the waveguide and the PSA layer and is thus trapped within the light guiding layer. Light interacts with the light turning layer only once upon incidence and thereafter does not interact with the light turning layer where the light may be scattered, absorbed or diffracted into free space. Therefore, embodiments comprising a PSA layer having lower refractive index than the light guiding material can have lower loss as compared to embodiments without a PSA layer having lower refractive index than the light guiding material.

Consider two rays of light 210 and 211 that are incident at angles θ₁ and θ₂ respectively on the upper surface of the embodiment 2000 as shown in FIG. 2A. The angle of incidence of ray 211 being equal to the angle of incidence of ray 108 referred to in FIG. 1D. The angle turning layer 209 turns the direction of rays 210 and 211 such that they are incident on the prismatic light guide 201 within the cones of acceptance 206a and 206b of the prismatic light guide 201. Thus by disposing an angle turning layer forward of the prismatic light guide 201, rays of light which would otherwise not have been guided can be converted into guided modes of the prismatic light guide 201.

The angle turning layer 209 may comprise a first set of volume, surface relief features or a combination thereof that are configured to turn the rays of light incident at a first angle to a second angle. In various embodiments, the second angle can be more normal than the first angle. The angle turning layer 209 may comprise a second set of volume, surface relief features or a combination thereof that are configured to turn the rays of light incident at a third angle to a fourth angle. The first and second set of diffractive features may be include in a single angle turning layer 209 or on multiple angle turning layers. For example, in FIG. 2B, the angle turning layer 209 comprises a first set of diffractive features such that ray of light 212 incident on the embodiment 2010 at an angle γ₁ is turned by the angle turning layer 209 such that ray 212 is incident on the prismatic light guide 201 at near normal incidence and is subsequently guided within the light guide 201. The guided ray of light 212 may exit the light guide 201 after striking the edge of the light guide 201 and may be optically coupled to the photo cell 203a. Lenses or light pipes may be used to optically couple light from the light guide 201 to the photo cell 203a. In one embodiment, for example, the light guide 201 may be devoid of prismatic features 202 towards the end closer to the photo cell 203a. The portion of the light guide 201 without any prismatic features may function as a light pipe.

The embodiment 2010 shown in FIG. 2B further comprises a second set of diffractive features such that ray of light 213 incident on the embodiment 2010 at an angle γ₂ is turned by the angle turning layer 209 such that ray 213 is incident on the prismatic light guide 201 at near normal incidence and is subsequently guided within the light guide 201 and coupled into a photo cell 203b.

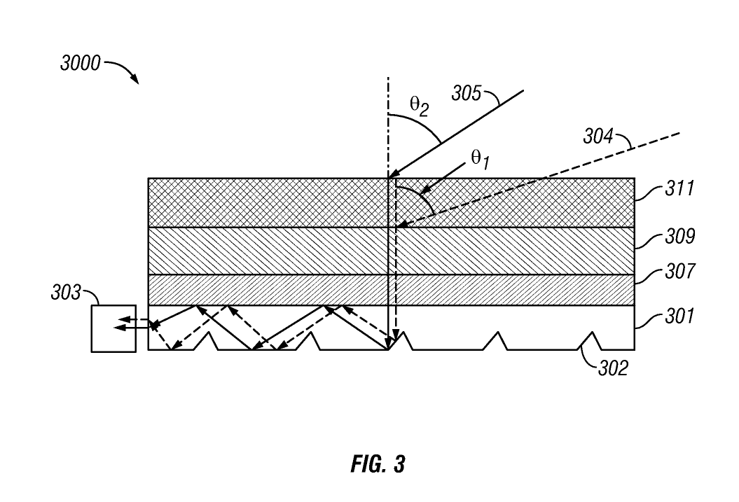

The embodiment 3000 illustrated in FIG. 3 comprises two angle turning layers 309 and 311 disposed forward of the prismatic light guide layer 301 comprising prismatic features 302. The first angle turning layer 309 comprises a first set of diffractive features such that ray of light 304 incident on the embodiment 3000 at an angle θ₁ is turned by the angle turning layer 309 such that ray 304 is incident on the prismatic light guide 301 at near normal incidence and is subsequently guided within the light guide 301 and directed towards a photo cell 303. Ray of light 304 is transmitted through the second angle turning layer 311 without being turned or diffracted.

The second angle turning layer 311 comprises a second set of diffractive features such that ray of light 305 incident on the embodiment 3000 at an angle θ₂ is turned by the angle turning layer 311 such that ray 305 is incident on the prismatic light guide 301 at near normal incidence and is subsequently guided within the light guide 301 and directed towards a photo cell 303. Ray of light 305 is transmitted through the first angle turning layer 309 without being turned or diffracted after it has been turned or diffracted by the second angle turning layer 311. Angle turning layers 309 and 311 may be joined to the light guide 301 by an adhesive layer 307.

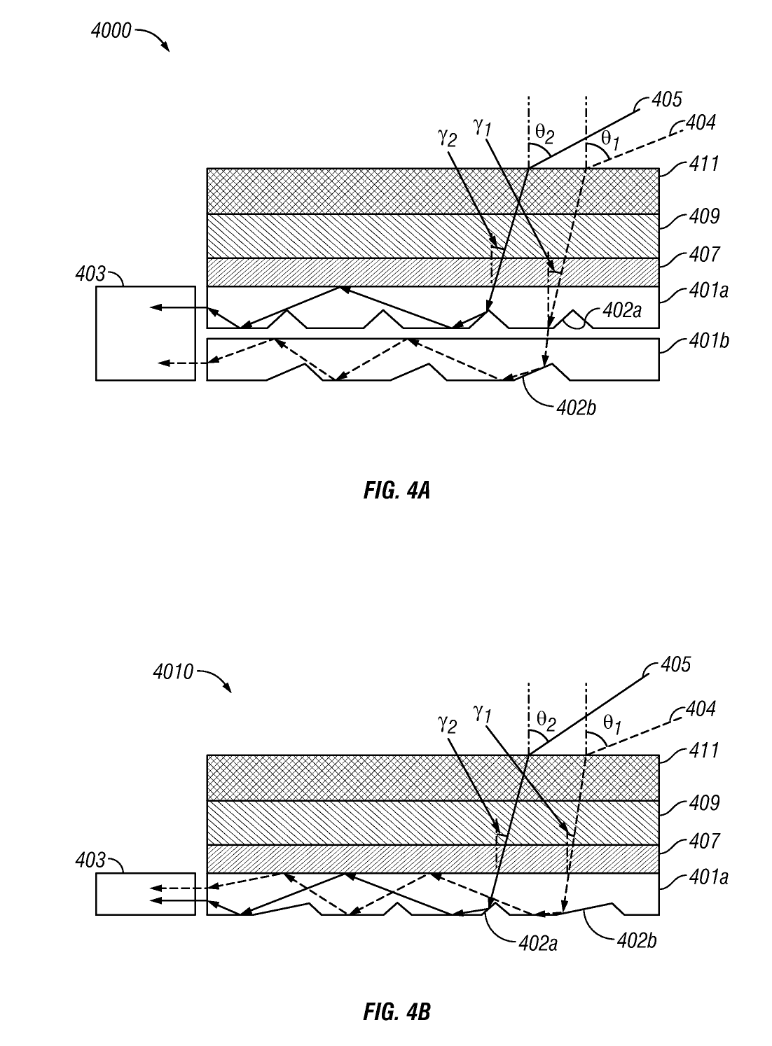

FIG. 4A shows an embodiment 4000 comprising two prismatic light guides 401a and 401b disposed laterally with respect to an edge of a photo cell 403. Light guide 401a further comprises relatively narrow prismatic features 402a and light guide 401b further comprises relatively wide angled facets 402b. The prismatic features 402a and 402b can be offset with respect to each other. Offsetting the prismatic features 402a and 402b in this manner reduces the spaces between the features and increases the density of the prismatic features. Offsetting the features may increase the amount of light optically coupled to the photo cell 403 thereby increasing the electrical output of the photo cell 403. Since the light guide layers 401a and 401b can be thin, it is possible to stack multiple light guide layers in this manner and increase the amount of light coupled to the PV cell 403. The number of layers that can be stacked together depends on the size and/or thickness of each layer and the scattering loss at the interface of each layer. In some embodiments, at least ten light guide layers may be stacked together. In various embodiments, more or less layers may be used. Angle turning layers 409 and 411 may be joined to the light guide layers by an adhesive layer 407.

Ray of light 405 that is incident on the embodiment 4000 at an angle θ₂ is turned by the angle turning layer 411 such that ray of light 405 is incident on the prismatic light guide 401a at an angle γ₂ and is subsequently guided within the prismatic light guide 401a and coupled into a photocell 403. Ray of light 404 that is incident on the embodiment 4000 at an angle θ₁ is turned by the angle turning layer 409 such that ray of light 404 is incident on the prismatic light guide 401b at an angle γ₁ and is subsequently guided within the prismatic light guide 401b and coupled into the photocell 403. One possible advantage of this design is that light can be collected at a wide range of angles efficiently without mechanically rotating the film. FIG. 4B illustrates an alternate embodiment 4010 comprising both narrow and wide angled facets on the same light guide 401a.

In one example, the angle turning layer 409 and 411 of the embodiments illustrated in FIGS. 4A and 4B can comprise multiple diffractive feature such that light from the sun is efficiently turned and guided within the prismatic light guides at multiple times during the day and at different times of the year. An advantage of using an angle turning layer to turn rays of light incident at multiple angles such that these rays can be guided within a prismatic light guiding plate, sheet or film and can be directed towards a photo cell is that lesser number of photo cells may be needed to achieve the desired electrical output. Thus this technique may possibly reduce the cost of generating energy with photo cells.

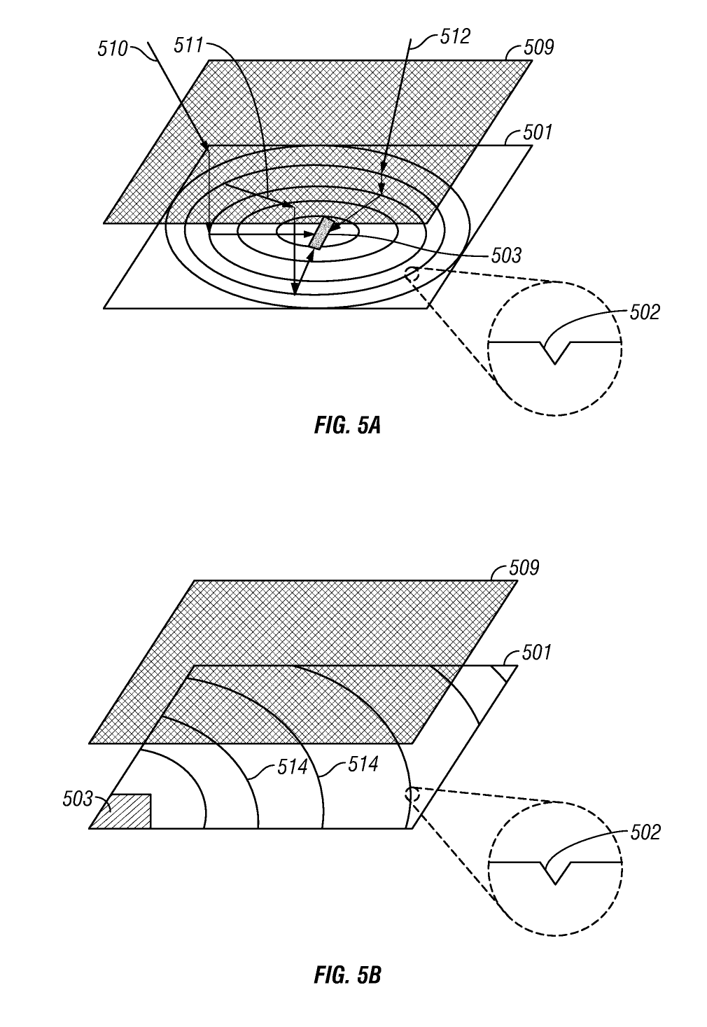

FIG. 5A illustrates an embodiment using a multi angle approach. In one embodiment, the elongated facets of the prismatic features or v grooves have non linear extent. The particular embodiment illustrated in FIG. 5A comprises a light guiding plate, sheet or film 501 formed from an optically transmissive material. Grooves are arranged along concentric circles on the surface of the light guiding plate 501. In some embodiments, the grooves may be disposed along elliptical paths. Other curvilinear configurations are also possible. These grooves may be v shaped grooves as illustrated by the cross-section 502. V-grooves that are nonlinear (for example, concentric) can be fabricated using a similar fabrication process as linear v-grooves. An angle turning layer 509 is disposed over the light guiding plate 501 such rays of light 510, 511 and 512 having different azimuthal angles are turned by the angle turning layer and subsequently turned by the v grooves towards a photo cell 503. In some embodiments, the photocell may be placed at the center of the concentric pattern. In some embodiments, the photocell may be disposed away from the center of the concentric pattern.

In another embodiment, illustrated in FIG. 5B, a photo cell 503 may be positioned at one corner of a light guiding plate, sheet or film 501. The light guiding plate, sheet or film may have rectangular, square or some other geometry. Grooves may be formed on the light guiding plate, sheet or film along curves 514. The centers of the curves 514 may not correspond to the center of the light guiding plate, sheet or film 501. The centers of the curves 510 may be closer to the corner with the photo cell 503 than the other corner. The grooves may be concave and may face the photo cell 503. An angle turning layer 509 may be disposed forward of the light guiding plate, sheet or film such that ambient light is directed towards the curved grooves 514 and is subsequently turned and coupled into the photo cell 503. Such a design comprising curvilinear prismatic features or grooves may be more efficient in light collecting than the design comprising photo cells disposed along one edge of a linear prismatic film and may enable use of smaller photocell.

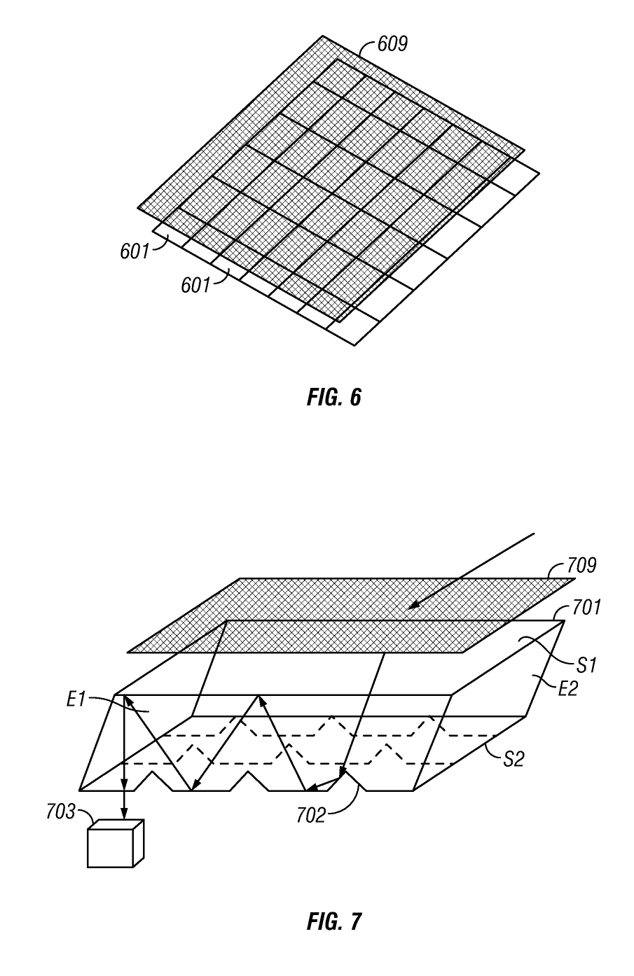

In some embodiments the length of the light guide may be limited to tens of inches to reduce loss due to reflections. However, limiting the length of the light guide may reduce the area over which light is collected. In some applications it may be advantageous to collect light over a large area. One approach to collect light over a large area can be a matrix pattern of micro-structure shown in FIG. 6. The embodiment shown in FIG. 6 illustrates a plurality of elements 601 arranged in a matrix pattern. The matrix pattern may comprise of a plurality of rows and columns. The number of rows can be equal to the number of columns. The number of elements in any two rows may be different. Similarly, the number of elements in any two columns may be different as well. In some embodiments, the matrix pattern may be irregular. Elements in the matrix comprise a light guiding plate, sheet or film with a plurality of v groove patterns formed thereon. Other groove patterns besides v grooves can be used as well. Elements in the matrix may contain the same or different microstructure pattern. For example, the microstructure pattern in the different elements may vary in size, shape, orientation and type. Thus different elements in the matrix may collect ambient light (e.g. sunlight) at different angles. Photo cells may be distributed within the periphery of the matrix (e.g. between adjacent light guides) as well as along the periphery of the matrix. An angle turning layer 609 may be disposed forward of the matrix pattern. The different regions of the angle turning layer 609 may comprise different volume or surface relief features. In some embodiments, the angle turning layer 609 may comprise a single plate, sheet or film. In other embodiments, the angle turning layer may comprise a plurality of plate, sheet or film disposed over each element of the matrix. The method disclosed above may be advantageous in fabricating large panels of light collectors coupled to a plurality of photo cells for example, that can be fixed to roof tops of residential and commercial buildings.

In the embodiment illustrated in FIG. 2A, the photo cell is butted up against the edge of the light guiding plate, sheet or film 201. Instead, in some embodiments, it may be advantageous to bevel the light guiding plate, sheet or film at its edge so that light is redirected out of the light guiding plate, sheet or film (e.g. bottom or top of the light guide) towards a photo cell as shown in FIG. 7. FIG. 7 illustrates an embodiment with a beveled light guiding plate, sheet or film 701 comprising prismatic features 702. The perspective view of the embodiment shown in FIG. 7 shows a light guide with an upper surface S1 and a lower surface S2. The upper and lower surfaces S1 and S2 are bound on the left by an edge surface E1 and on the right by an edge surface E2. The edge surfaces E1 and E2 are inclined with respect to the upper and lower surfaces S1 and S2. The angle of inclination of the edge surface E1 and E2 with respect to upper and lower surface S1 and S2 may not be equal to 90 degrees. The embodiment shown in FIG. 7 further comprises an angle turning layer 709 comprising diffractive features. A ray of light incident on the upper surface of the angle turning layer 709 is turned and directed towards the light guide 701 such that it is turned into the light guide 701 by the prismatic feature 702 and guided along the beveled light guide by total internal reflection from the upper and lower surfaces S1 and S2. On striking the inclined edge E1 the guided light ray may be directed out of the light guide close to the normal to the lower surface S2 towards a photo cell 703 disposed rearward of the light guiding plate or film 701. Beveling the edge of the light guiding plate, sheet or film 701 may simplify the alignment between the photo cell 703 and the light guiding plate, sheet or film 701.

It is conceivable to arrange a plurality of beveled light guides comprising prismatic features in a matrix pattern similar to the embodiment described in FIG. 6. The photocells in such an embodiment may be disposed for example underneath the matrix pattern. Ambient light incident on the upper surface of the matrix pattern is directed by the beveled edges of the light guides towards the photo cells disposed for example, rearward of the matrix pattern.

In some embodiments, conical cavities may be formed on the surface of the light guiding plate, sheet or film instead of elongate grooves. The conical cavities may be distributed throughout the light guiding plate, sheet or film in a random or ordered manner. The conical cavities may have a circular or an elliptical cross section or other shapes. The conical cavities can accept light in a plurality of directions and redirect light along a plurality of directions due to their three dimensional structure.

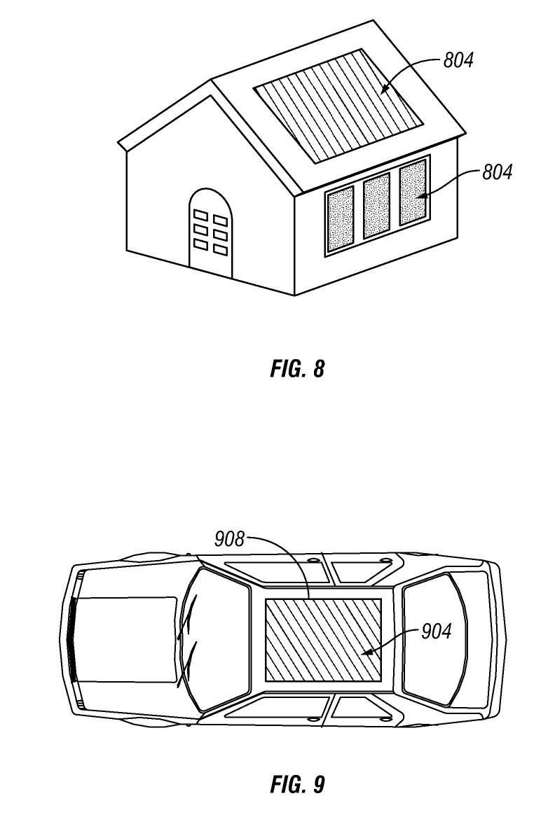

The method of using a light collecting plate, sheet or film comprising prismatic features and angle turning layers to collect, concentrate and direct light to a photo cell can be used to realize solar cells that have increased efficiency and can be inexpensive, thin and lightweight. The solar cells comprising a light collecting plate, sheet or film coupled to a photo cell may be arranged to form panels of solar cells. Such panels of solar cells can be used in a variety of applications. For example, a panel of solar cells 804 comprising a plurality of light collecting plate, sheet or film optically coupled to photo cells may be mounted on the roof top of a residential dwelling or a commercial building or placed on doors and windows as illustrated in FIG. 8 to provide supplemental electrical power to the home or business. The light collecting plate, sheet or film may be formed of a transparent or semi-transparent plate, sheet or film. The light collecting sheets may be transparent and possibly reduce glare to see through the window if placed thereon. The prismatic light collecting plate, sheet or film may be colorized (for example red or brown) for aesthetic purposes. In some embodiments, the light collecting sheets may be tinted or colorized to block light. The light collecting plate, sheet or film may be rigid or flexible. In some embodiments, the light collecting plate, sheet or film may be sufficiently flexible to be rolled. In other embodiments, the prismatic sheets may have wavelength filtering properties to filter out the ultra-violet radiation.

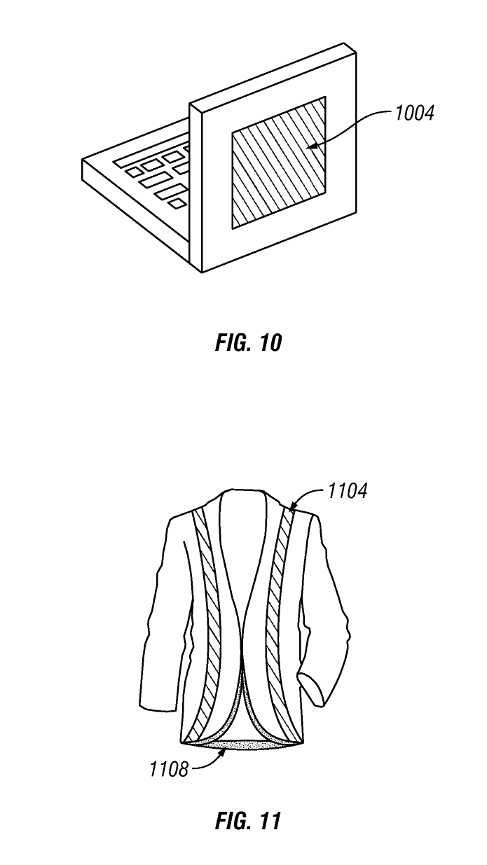

In other applications, light collecting plate, sheet or film may be mounted on cars and laptops as shown in FIGS. 9 and 10 respectively to provide electrical power. In FIG. 9 the light collecting plate, sheet or film 904 is mounted to the roof of an automobile. Photo cells 908 can be disposed along the edges of the light collector 904. The electrical power generated by the photo cells 908 can be used for example, to recharge the battery of a vehicle powered by gas, electricity or both or run electrical components as well. In FIG. 10, the light collecting plate, sheet or film 1004 may be attached to the body (for example external casing) of a laptop. This is advantageous in providing electrical power to the laptop in the absence of electrical connection. The light guiding collector optically coupled to photo cells may also be used to recharge the laptop battery.

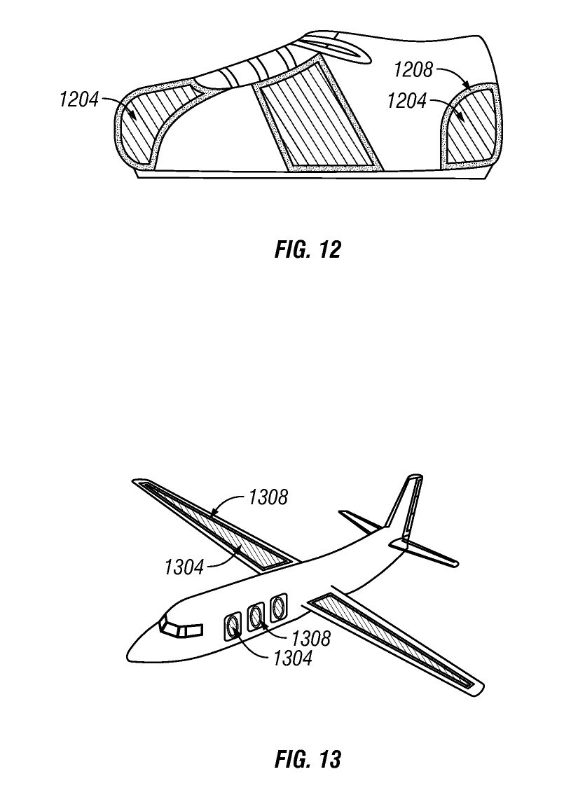

In alternate embodiments, the light collecting plate, sheet or film optically coupled to photo cells may be attached to articles of clothing or shoes. For example FIG. 11 illustrates a jacket or vest comprising the light collecting plate, sheet or film 1104 optically coupled to photo cells 1108 disposed around the lower periphery of the jacket or vest. In alternate embodiments, the photo cells 1108 may be disposed anywhere on the jacket or vest. The light collecting plate, sheet or film 1104 may collect, concentrate and direct ambient light to the photo cells 1108. The electricity generated by the photo cells 1108 may be used to power handheld devices such as PDAs, mp3 players, cell phone etc. The electricity generated by the photo cells 1108 may also be used to light the vests and jackets worn by airline ground crew, police, fire fighters and emergency workers in the dark to increase visibility. In another embodiment illustrated in FIG. 12, the light collecting plate, sheet or film 1204 may be disposed on a shoe. Photo cells 1208 may be disposed along the edges of the light collecting plate, sheet or film 1204.

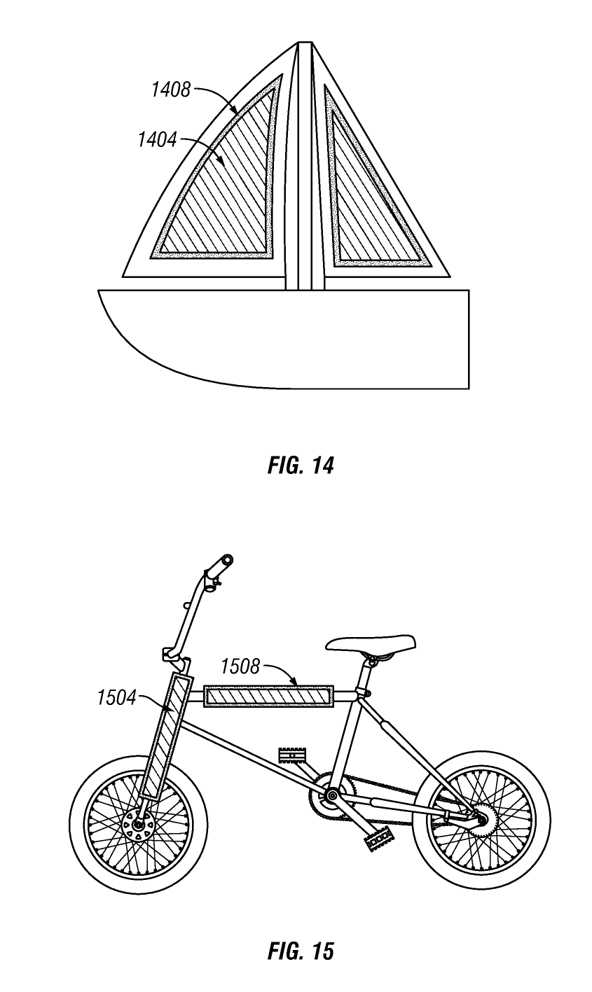

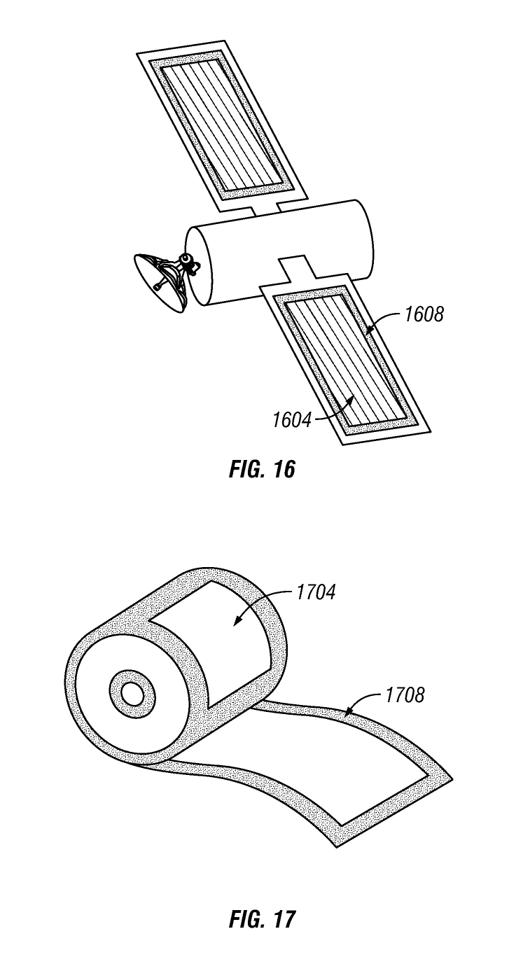

Panels of solar cells comprising of prismatic light collecting plate, sheet or film coupled to photo cells may be mounted on aircrafts, trucks, trains, bicycles, boats and spacecrafts as well. For example as shown in FIG. 13, light collecting plate, sheet or film 1304 may be attached to the wings of an airplane or window panes of the airplane. Photo cells 1308 may be disposed along the edges of the light collecting plate, sheet or film as illustrated in FIG. 13. The electricity generated may be used to provide power to parts of the aircraft. FIG. 14 illustrates the use of light collectors coupled to photo cells to power for example, navigation instruments or devices in a boat for example, refrigerator, television and other electrical equipments. The light collecting plate, sheet or film 1404 is attached to the sail of a sail boat or alternately to the body of the boat. PV cells 1408 are disposed at the edges of the light collecting plate, sheet or film 1404. In alternate embodiments, the light collecting plate, sheet or film 1404 may be attached to the body of the boat for example, the cabin, hull or deck. Light collecting plate, sheet or film 1504 may be mounted on bicycles as illustrated in FIG. 15. FIG. 16 illustrates yet another application of the light collecting plate, sheet or film 1604 optically coupled to photo cells 1608 to provide power to communication, weather and other types of satellites.

FIG. 17 illustrates a light collecting sheet 1704 that is sufficiently flexible to be rolled. The light collecting sheet is optically coupled to photo cells 1708. The embodiment described in FIG. 17 may be rolled and carried on camping or backpacking trips to generate electrical power outdoors and in remote locations where electrical connection is sparse. Additionally, the light collecting plate, sheet or film that is optically coupled to photo cells may be attached to a wide variety of structures and products to provide electricity.

The light collecting plate, sheet or film optically coupled to photo cells may have an added advantage of being modular. For example, depending on the design, the photo cells may be configured to be selectively attachable to and detachable from the light collecting plate, sheet or film. Thus existing photo cells can be replaced periodically with newer and more efficient photo cells without having to replace the entire system. This ability to replace photo cells may reduce the cost of maintenance and upgrades substantially.

A wide variety of other variations are also possible. Films, layers, components, and/or elements may be added, removed, or rearranged. Additionally, processing steps may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

The examples described above are merely exemplary and those skilled in the art may now make numerous uses of, and departures from, the above-described examples without departing from the inventive concepts disclosed herein. Various modifications to these examples may be readily apparent to those skilled in the art, and the generic principles defined herein may be applied to other examples, without departing from the spirit or scope of the novel aspects described herein. Thus, the scope of the disclosure is not intended to be limited to the examples shown herein but is to be accorded the widest scope consistent with the principles and novel features disclosed herein. The word “exemplary” is used exclusively herein to mean “serving as an example, instance, or illustration.” Any example described herein as “exemplary” is not necessarily to be construed as preferred or advantageous over other examples.

What is claimed is:

1. A light collecting device comprising:
a light guide having top and bottom surfaces, said light guide guiding light therein by multiple total internal reflections at said top and bottom surfaces;
a plurality of diffractive features disposed to receive light at a first angle with respect to the normal to the top surface of said light guide; and
a plurality of prismatic features disposed rearward of the plurality of diffractive features,
wherein said diffractive features are configured to redirect said light at a second angle towards the plurality of prismatic features,
wherein said second angle is more normal than the first angle, and
wherein said plurality of prismatic features are configured to turn the light redirected by the diffractive features such that said light is guided in the light guide by total internal reflection from said top and bottom surfaces of the light guide.

2. The light collecting device of claim 1, wherein said light guide comprises a plate, sheet, or film.

3. The light collecting device of claim 1, wherein said light guide is flexible.

4. The light collecting device of claim 1, wherein said light guide comprises a thin film.

5. The light collecting device of claim 1, wherein said light guide comprises glass.

6. The light collecting device of claim 1, wherein said light guide comprises plastic.

7. The light collecting device of claim 6, wherein said light guide comprises acrylic, polycarbonate, polyester or cyclo-olefin polymer.

8. The light collecting device of claim 1, wherein said plurality of diffractive features comprises volume features.

9. The light collecting device of claim 1, wherein said plurality of diffractive features comprises surface-relief features.

10. The light collecting device of claim 1, further comprising a holographic layer comprising said plurality of diffractive features.

11. The light collecting device of claim 10, further comprising multiple holograms in said holographic layer.

12. The light collecting device of claim 1, further comprising a first holographic layer comprising a first set of plurality of diffractive features and a second holographic layer comprising a second set of plurality of diffractive features.

13. The light collecting device of claim 12, wherein the first holographic layer and the second holographic layer are laminated together.

14. The light collecting device of claim 1, further comprising a diffractive layer comprising said plurality of diffractive features and a planarized layer thereon.

15. The light collecting device of claim 1, wherein the first angle is approximately between 10 degrees and 90 degrees from the normal to the surface of the light guide.

16. The light collecting device of claim 1, wherein the second angle is approximately normal to the surface of the light guide.

17. The light collecting device of claim 1, wherein the plurality of diffractive features are formed on the top surface of said light guide.

18. The light collecting device of claim 1, wherein said plurality of prismatic features comprise elongate grooves.

19. The light collecting device of claim 18, wherein said elongate grooves are straight.

20. The light collecting device of claim 18, wherein said elongate grooves are curved.

21. The light collecting device of claim 1, wherein said plurality of prismatic features comprises planar facets angled with respect to each other.

22. The light collecting device of claim 21, wherein planar facets are oriented at an angle of between 15 degrees to 85 degrees with respect to each other.

23. The light collecting device of claim 1, wherein prismatic features comprise pits.

24. The light collecting device of claim 23, wherein said pits are conical.

25. The light collecting device of claim 23, wherein said pits have at least three sides comprising tilted surface portions.

26. The light collecting device of claim 1, wherein the prismatic features have the same shape.

27. The light collecting device of claim 1, wherein at least some of the prismatic features have different shapes.

28. The light collecting device of claim 1, wherein said plurality of prismatic features are formed on the bottom surface of said light guide.

29. The light collecting device of claim 1, wherein said plurality of prismatic features are included in one or more prismatic films.

30. The light collecting device of claim 29, wherein said one or more prismatic films are disposed rearward of said light guide.

31. The light collecting device of claim 29, further comprising a first prismatic film comprising a first set of prismatic features and a second prismatic film comprising a second set of prismatic features and
wherein at least some of said first set of prismatic features in the first prismatic film are laterally offset with respect to some of said second set of prismatic features in the second prismatic film.

32. The light collecting device of claim 31, wherein at least some of said first set of prismatic features in the first prismatic film are shaped differently than some of said second set of prismatic features in the second prismatic film.

33. The light collecting device of claim 1, wherein said plurality of prismatic features extend along a plurality of parallel linear paths.

34. The light collecting device of claim 1, wherein said prismatic features extend along plurality of concentric circular curved paths.

35. The light collecting device of claim 1, wherein said plurality of prismatic features extends along a plurality of elliptical curved paths.

36. The light collecting device of claim 1, wherein said plurality of prismatic features further comprises:
a first section comprising a first set of prismatic features; and
a second section comprising a second set prismatic features,
wherein said first and second sections are disposed laterally with respect to each other and said first set of prismatic features have a different shape or orientation than said second set of prismatic features.

37. The light collecting device of claim 1, further comprising one or more adhesive layer.

38. The light collecting device of claim 37, wherein the adhesive layer comprises pressure sensitive adhesive.

39. The light collecting device of claim 37, wherein the adhesive layer is disposed between the plurality of diffractive features and the top surface of the light guide.

40. The light collecting device of claim 37, wherein the adhesive layer is disposed between the plurality of prismatic features and the bottom surface of the light guide.

41. The light collecting device of claim 37, wherein the refractive index of the adhesive layer is less than the refractive index of the light guide material.

42. The light collecting device of claim 41, wherein the adhesive layer is configured as a cladding layer to increase confinement in the light guide.

43. The device of claim 1, further comprising a first photocell configured to receive light guided in said light guide.

44. The device of claim 43, wherein said first photocell comprises a photovoltaic cell.

45. The device of claim 43, wherein said first photocell is butt coupled to an edge of said light guide.

46. The device of claim 43, wherein said light guide includes a beveled surface and said first photocell is disposed with respect to said beveled surface to receive light reflected therefrom.

47. The device of claim 46, wherein said first photocell is disposed below said first light guide.

48. The device of claim 43, wherein said first photocell is disposed at a corner of said light guide.

49. The device of claim 43, further comprising a second photocell configured to receive light guided in said light guide.

50. The device of claim 43, wherein said first light guide is disposed on an automobile, aircraft, spacecraft, or nautical vessel.

51. The device of claim 43, wherein said first light guide is disposed on a bicycle, stroller, or trailer.

52. The device of claim 43, wherein said first light guide is disposed on an article of clothing.

53. The device of claim 52, wherein said first light guide is disposed on a shirt, pants, shorts, coat, jacket, vest, hat, or footwear.

54. The device of claim 43, wherein said first light guide is disposed on a computer, a cell phone, or a personal digital assistant.

55. The device of claim 43, wherein said first light guide is disposed on an architectural structure.

56. The device of claim 55, wherein said first light guide is disposed on a house or building.

57. The device of claim 43, wherein said first light guide is disposed on an electrical device.

58. The device of claim 57, wherein said first light guide is disposed on a light, phone, or motor.

59. The device of claim 43, wherein said first light guide is on a tent or a sleeping bag.

60. The device of claim 43, wherein said first light guide is rolled-up or folded.

61. A light collecting device comprising:
a means for guiding light, said light guiding means having top and bottom surfaces, said light guiding means configured to guide light therein by multiple total internal reflections at said top and bottom surfaces;
a plurality of means for diffracting light, said light diffracting means disposed to receive light at a first angle with respect to the normal to the top surface of said light guiding means; and
a plurality of means for turning light, said light turning means disposed rearward of the plurality of diffracting means,
wherein said plurality of diffracting means are configured to redirect said light at a second angle towards the plurality of light turning means,
wherein said second angle is more normal than the first angle, and
wherein said plurality of light turning means are configured to turn the light redirected by the diffracting means such that said light is guided in the light guiding means by total internal reflection from said top and bottom surfaces of the light guiding means.

62. The light collecting device of claim 61, wherein the light guiding means comprises a light guide, or the plurality of diffracting means comprises a plurality of diffractive features, or the plurality of light turning means comprises a plurality of prismatic features.

63. A method of manufacturing a light collecting device, the method comprising:
providing a light guide having top and bottom surfaces, said light guide configured to guide light therein by multiple total internal reflections at said top and bottom surfaces;
providing a plurality of diffractive features, said plurality of diffractive features configured to receive light at a first angle with respect to the normal to the top surface of the light guide; and
providing a plurality of prismatic features, said plurality of prismatic features disposed rearward of the plurality of diffractive features,
wherein said plurality of diffractive features are configured to redirect said light at a second angle towards the plurality of prismatic features,
wherein said second angle is more normal than the first angle, and
wherein said plurality of prismatic features are configured to turn the light redirected by the diffractive features such that said light is guided in the light guide by total internal reflection from said top and bottom surfaces of the light guide.

64. The method of claim 63, wherein the plurality of prismatic features are disposed rearward of the light guide.

65. The method of claim 63, wherein the plurality of prismatic features are provided by molding.

66. The method of claim 63, wherein the plurality of prismatic features are provided by embossing.

67. The method of claim 63, wherein the plurality of prismatic features are provided by etching.

68. The method of claim 63, wherein the plurality of diffractive features are disposed forward of the light guide.

69. The method of claim 63, wherein the plurality of diffractive features are provided in a layer that is disposed forward of the light guide.
